(19) United States
(12) Patent Application Publication
(10) Pub. No.: US 2002/0130589 A1
(43) Pub. Date: Sep. 19, 2002

(54) Piezoelectric vibrator, piezoelectric vibration apparatus for using the same and manufacturing method therefor

(76) Inventors: Hiroshi Hamada, Tokyo (JP); Yukihiro Matsui, Tokyo (JP); Yasuyuki Inomata, Tokyo (JP); Hideki Oikawa, Tokyo (JP)

Correspondence Address: BACON & THOMAS, PLLC, 625 SLATERS LANE, FOURTH FLOOR, ALEXANDRIA, VA, 22314

(21) Appl. No.: 10/056,112

(22) Filed: Jan. 28, 2002

(30) Foreign Application Priority Data
Jan. 29, 2001 (JP) 2001-19445

(51) Int. Cl. H01L 41/04

(52) U.S. Cl. 310/324; 310/334

(57) ABSTRACT

A piezoelectric vibrator with a smaller diameter may have a higher sound pressure to obtain a piezoelectric vibration apparatus with a smaller diameter and a thinner thickness. Although the primary electrode is uniformly coated on the primary side, it is not coated on all the primary side of the piezoelectric film and it is made of a continuous mesh metal film. Accordingly, a driving voltage may be applied on the piezoelectric film while there are some portions on the primary side on which the metal film is partially uncoated so that the curvature restraint of the piezoelectric film due to the primary electrode may be reduced. The contact electrode with a higher metal film occupation ratio than that of the primary electrode is coated so that the contact electrode may be used as a soldering portion for connecting thereto the terminal.

### FIELD OF THE INVENTION

The present invention relates to a piezoelectric vibrator, a piezoelectric vibration apparatus for using the piezoelectric vibrator and a method for manufacturing the piezoelectric vibrator; and, more particularly, to a piezoelectric vibrator capable of obtaining a higher sound pressure with a smaller diameter thereof and a thinner thickness thereof.

### BACKGROUND OF THE INVENTION

In a conventional piezoelectric vibration apparatus, a piezoelectric vibrator has been used. The piezoelectric vibrator includes a vibration plate and a piezoelectric film attached on the vibration plate. The vibration plate is made of a circular metal plate and the piezoelectric film has a circular piezoelectric ceramic plate and two electrodes installed, respectively, on two sides of the circular piezoelectric ceramic plate. If a driving voltage is applied between two electrodes of the piezoelectric film, the piezoelectric film may be displaced along a direction orthogonal to the driving voltage. The displacement of the piezoelectric film may be detected from the expansion and contraction of the piezoelectric film along the diameter thereof. The expansion and contraction results in a curvature in the vibration plate so that the piezoelectric vibrator may vibrate to thereby generate a sound effective vibration.

Such piezoelectric vibration apparatus may be used as a receiver in a cellular phone or a cordless phone. The piezoelectric vibration apparatus incorporated in the cellular phone or the cordless phone is connected to an electrical circuit. If a voice signal generated from the electrical circuit is applied between two electrodes of the piezoelectric film, a voice may be generated.

Since a smaller and high-intelligent cellular phone is being developed, a smaller piezoelectric vibration apparatus is also required. In other words, the piezoelectric vibration apparatus including a case or a frame must have a smaller diameter and a thinner thickness. In order to satisfy those conditions, the piezoelectric vibrator that generates a sound must have a smaller diameter and a thinner thickness.

If, however, the piezoelectric vibrator has a smaller diameter, it is natural that the sound pressure is decreased. Since the sound pressure in, especially, a lower frequency band, e.g., lower than hundreds of Hz, is considerably decreased, only a high frequency sound stands out to reconstruct an artificial sound. Accordingly, the sound pressure is decreased and the sound quality is also deteriorated.

### SUMMARY OF THE INVENTION

It is, therefore, an object of the present invention to provide a piezoelectric vibrator capable of obtaining a higher sound pressure with a smaller diameter thereof, a piezoelectric vibration apparatus for using the piezoelectric vibrator with a smaller diameter thereof and a thinner thickness thereof and a method for manufacturing the piezoelectric vibrator.

In accordance with a preferred embodiment of the present invention, there is provided a piezoelectric vibrator comprising:

a vibration plate having a primary surface; and

a piezoelectric device attached on the primary surface of the vibration plate, wherein the piezoelectric device includes a piezoelectric film and two electrodes, respectively, formed on two sides of the piezoelectric film,

wherein one of the two sides of the piezoelectric film on which the vibration plate is not attached is a primary side and one electrode of two electrodes formed on the primary side is a primary electrode;

wherein the primary electrode is substantially uniformly coated on the primary side and made of a continuous mesh metal film.

In accordance with another preferred embodiment of the present invention, there is provided a piezoelectric vibration apparatus for using the piezoelectric vibrator.

In accordance with still another preferred embodiment of the present invention, there is provided a method for manufacturing the piezoelectric vibrator, wherein the mesh metal film is formed by a coherence process of a conduction paste.

### BRIEF DESCRIPTION OF THE DRAWINGS

The above and other objects and features of the present invention will become apparent from the following description of preferred embodiments given in conjunction with the accompanying drawings, in which:

FIG. 1 represents a partially cutaway exploded perspective view for illustrating components of a piezoelectric vibration apparatus in accordance with a first embodiment of the present invention;

FIG. 2 shows a cross sectional view for illustrating a neighboring region of a terminal of the piezoelectric vibration apparatus in accordance with the first embodiment of the present invention;

FIG. 3 depicts a plan view for partially illustrating an upper side of the piezoelectric vibration apparatus in accordance with the first embodiment of the present invention;

FIG. 4 presents a plan view for partially illustrating a lower side of the piezoelectric vibration apparatus in accordance with the first embodiment of the present invention;

FIG. 5 sets forth a simulation graph for a relation between a sound pressure decrement and a metal film occupation ratio in a primary electrode in accordance with the first embodiment of the present invention;

FIG. 6 displays an enlarged plan view on the primary electrode with a metal film occupation of 56.2% in accordance with the first embodiment of the present invention;

FIG. 7 exhibits an enlarged plan view on the primary electrode with a metal film occupation of 61.4% in accordance with the first embodiment of the present invention;

FIG. 8 demonstrates an enlarged plan view on the primary electrode with a metal film occupation of 76.3% in accordance with the first embodiment of the present invention;

FIG. 9 establishes an enlarged plan view on the primary electrode with a metal film occupation of 81.7% in accordance with the first embodiment of the present invention;

FIG. 10 is an enlarged plan view on the primary electrode with a metal film occupation of 85.4% in accordance with the first embodiment of the present invention;

FIG. 11 illustrates an enlarged view for a primary portion of the piezoelectric vibration apparatus in accordance with a second embodiment of the present invention;

FIG. 12A represents a cross-sectional view for illustrating a stack structure of a piezoelectric vibrator in accordance with the second embodiment of the present invention;

FIG. 12B presents a cross-sectional view for illustrating a stack structure of a piezoelectric vibrator in accordance with a third embodiment of the present invention; and

FIG. 13 shows a graph for illustrating a relation between a central displacement per one diameter and a ratio of an electrode thickness to a piezoelectric film thickness in accordance with the second embodiment of the present invention.

### DETAILED DESCRIPTION OF THE PREFERRED EMBODIMENTS

The present invention is susceptible of numerous physical embodiments, depending upon the environment and requirements of use, and substantial numbers of the herein shown and described embodiments have been made, tested and used, and all have performed in an eminently satisfactory manner.

### EXAMPLE 1

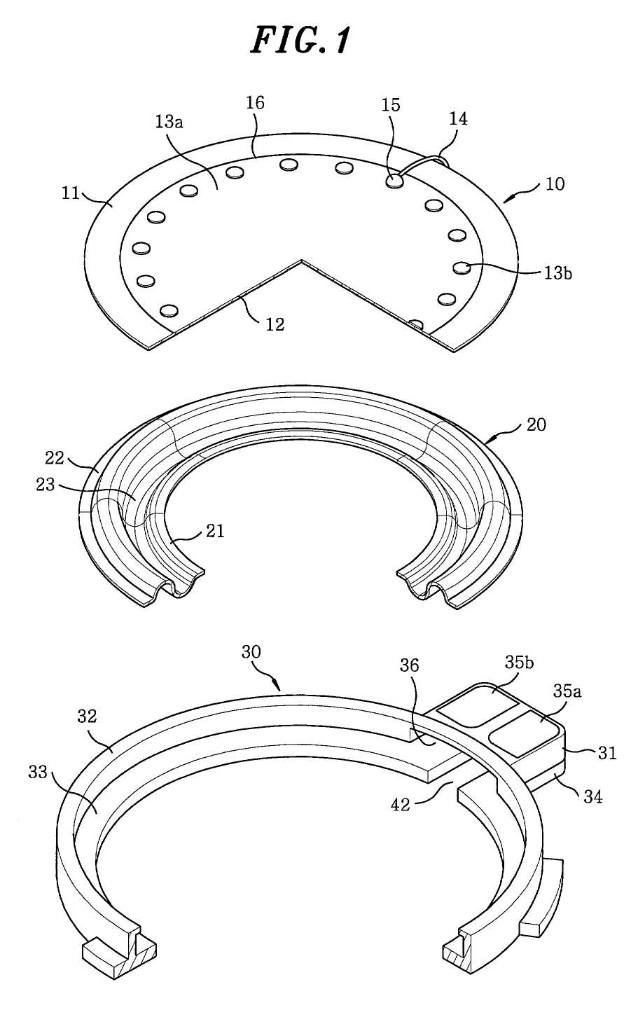

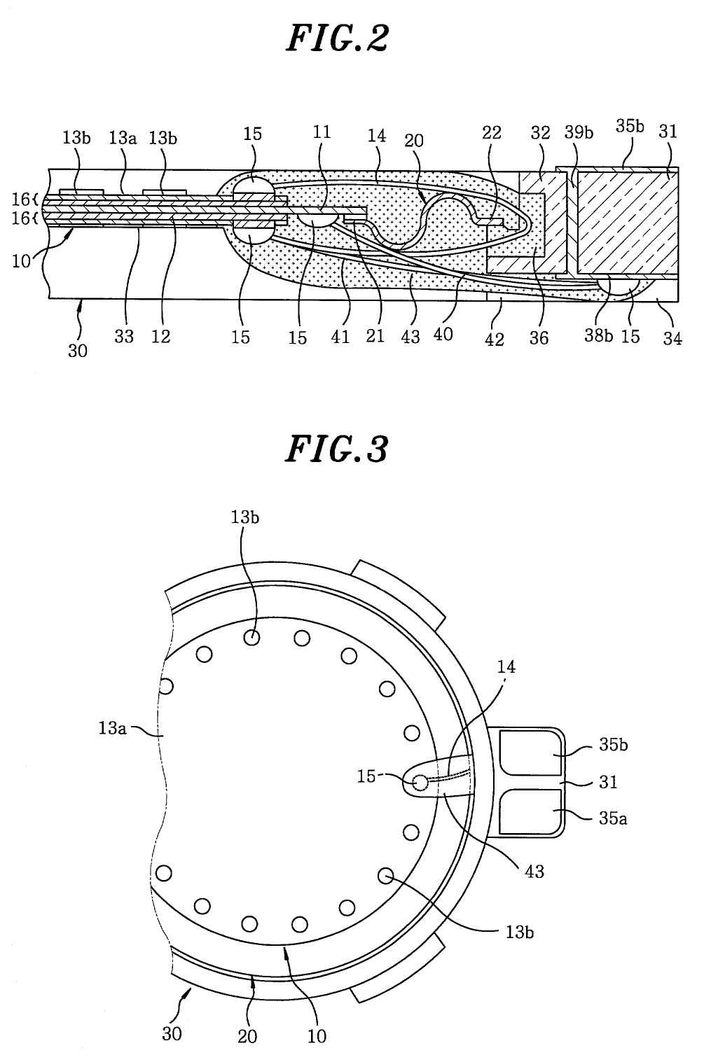

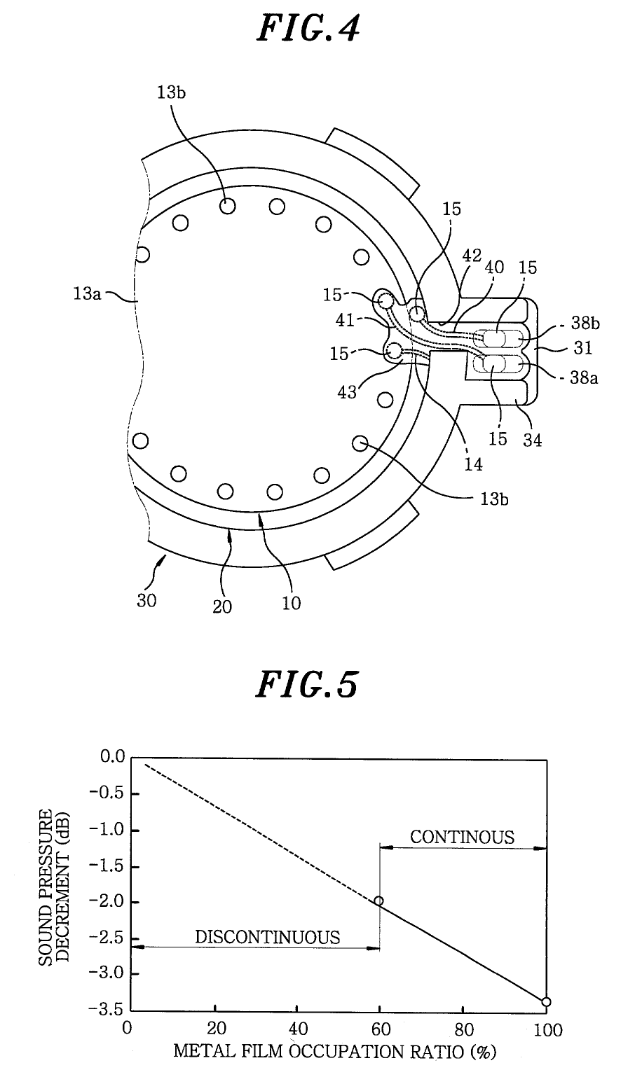

Referring to FIGS. 1 to 10, there is specifically illustrated a first embodiment in accordance with the present invention. FIG. 1 shows basic components of a piezoelectric vibration apparatus in accordance with the first embodiment of the present invention. Referring to FIG. 2, there is a primary cross-sectional view for illustrating a structure near to two terminals 35a and 35b of the piezoelectric vibration apparatus. Referring to FIGS. 3 and 4, there are shown plan views for partially illustrating an upper and a lower side near to two terminals 35a and 35b of the piezoelectric vibration apparatus. The piezoelectric vibration apparatus has a piezoelectric vibrator 10, a holding element 20 and a frame 30.

The piezoelectric vibrator 10 has a vibration plate 11 and a piezoelectric device 16 attached thereto, wherein the vibration plate 11 is made of circular metal plate and the piezoelectric device 16 has a piezoelectric film 12 and two electrodes formed on two primary sides of the piezoelectric film 12, respectively. One electrode of the piezoelectric device 16 is electrically attached around the center of the vibration plate 11. The piezoelectric film 12 is made of circular piezoelectric ceramic film. After a conduction paste is coated on two primary sides of the piezoelectric film 12, it is heat-treated to generate two electrodes. The piezoelectric film 12 is polarized along the direction of thickness.

A bimorph piezoelectric vibrator may be obtained by attaching two piezoelectric devices 16 on two primary surfaces of the vibration plate 11, respectively, while a unimorph piezoelectric vibrator may be made by attaching one piezoelectric device 16 on only one primary surface of the vibration plate 11. In the embodiment shown in FIGS. 2 to 4, the bimorph piezoelectric vibrator in which two piezoelectric devices 16 are attached on two primary surfaces of the vibration plate 11, respectively, has been used for illustration while the unimorph piezoelectric vibrator may be used on behalf of the bimorph piezoelectric vibrator.

A surface electrode of the piezoelectric film 12, i.e., an electrode of the piezoelectric film 12 opposite to the vibration plate 11, has a primary electrode 13a for uniformly coating a side of the piezoelectric film 12 and a plurality of contact electrodes 13b arranged with an equiangular distance along the inside of circumference of the primary electrode 13a.

The primary electrode 13a is made of a continuous mesh (insular or dappled) metal film and, therefore, there may exist some apertures which are partially uncoated with the metal film on the side of the piezoelectric film 12. The continuous mesh metal film represents that adjacent mesh metal films are continuous to each other, the primary electrode 13a is substantially continuous on the whole and there exists no metal film except the mesh metal film. It may be considered that there are many discontinuous mesh apertures on the metal film. If the mesh metal film has uniform width therein and regular direction thereof, it is preferably called as a lattice metal film. The lattice metal film is a typical type of the continuous mesh metal film.

To make the primary electrode 13a shaped with a mesh, a conductive paste is thinly coated on two sides of the piezoelectric film 12 and then it is heat-treated so that a binder component in the conductive paste may be burned and a metal component therein may be cohered. Since a coating thickness of the conductive paste on the piezoelectric film 12 depends on the ratio of the metal component to the binder component in the conductive paste, it cannot be uniformly defined but, for example, the coating thickness of silver pasta is preferably about 2.2 μm. If the silver paste with a thickness of 2.2 μm is heat-treated, an average film thickness of the silver paste decreases to be 2 μm or less.

Further, on behalf of the conductive paste itself, one or more non-metal component may be mixed in the conductive paste to fabricate a mesh or lattice metal film. Specifically, after ceramic powders with a particle diameter of about 0.1 μm to about 1.0 μm made of the same material as the piezoelectric film may be mixed in the conduction paste in the ratio of a powder to metal about 10 vol % to about 50 vol %, the mixed paste may be used as an electrode paste to form the lattice metal film. The ceramic powders are not confined to the same material as the piezoelectric film and other powders will do as long as they do not react with the piezoelectric film or the metal film to generate a poor electrode. On behalf of non-organic powders, organic materials such as organic emulsion may be used as long as they have no influence on the viscosity or decomposition of the electrode paste itself.

If a driving voltage is applied across two sides of the piezoelectric film 12 of the piezoelectric vibrator 10 through the primary electrode 13a formed thereon by the mesh metal film, the piezoelectric film 12 may be bent so that the vibration plate 11 may vibrate to generate a sound. Since there is no metal film except the mesh metal film itself on the side of the piezoelectric film 12, the restraint of the primary electrode 13a against the piezoelectric film 12 may be reduced. Since, further, the mesh metal film is continuous to each other, a voltage may be applied throughout the whole primary side of the piezoelectric film 12. The piezoelectric film 12 may be bent more easily to vibrate the vibration plate 11 and, accordingly, a higher sound pressure may be obtained.

Referring to FIG. 5, there is a simulation result for illustrating a sound pressure decrement as a function of a metal film occupation ratio while applying a driving voltage across two primary sides relative to a sound pressure under the metal film occupation ratio of 0%, wherein the metal film occupation ratio of 0% represents there is no metal film on the primary side of the piezoelectric film 12. If the metal film occupation ratio is 60%, the sound pressure decrement corresponds to about 2 dB while, if the metal film occupation ratio is 100%, i.e., all the primary surface of the piezoelectric film 12 is coated with the metal film to form the primary electrode 13a, the sound pressure decrement corresponds to about 3.3 dB.

Since, however, if the metal film occupation ratio is less than 60%, the mesh metal film is not continuous any more, the primary electrode 13a does not function as the electrode so that a voltage may not be applied to the piezoelectric film 12. Therefore, the sound pressure decrement for the metal film occupation ratio of 60% or less may be extrapolated from the sound pressure decrement under the metal film occupation ratio of 60% to 100% as shown with a dotted line in FIG. 5.

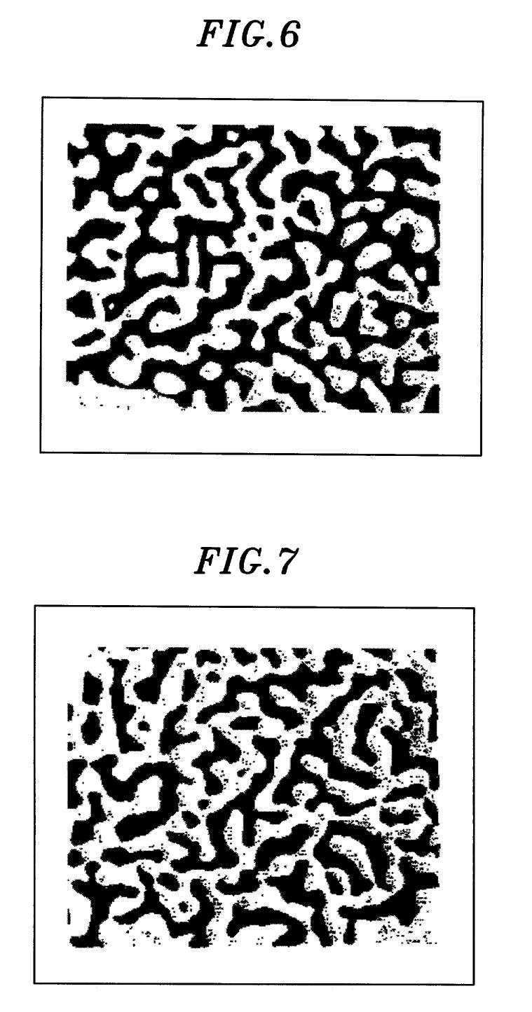

Referring to FIGS. 6 to 10, each picture is an enlarged view by a microscope for illustrating an occupation state of some portion of metal film coated on the side of the piezoelectric film 12 to form the primary electrode 13a. The white part represents a metal film while the black part represents a ground part of the piezoelectric film 12, i.e., a part on which there is no metal film. Further, the metal film to be detected was photographed by a scanning electron microscope (SEM) of 1000 magnifications, the contrast of the photograph of the metal film was digitized by using an image processing software and, then, the metal film occupation ratio has been calculated from the area of the white part, i.e., the metal film.

Referring to FIG. 6, there is shown a surface state of the primary electrode 13a formed on the side of the piezoelectric film 12 under a metal film occupation ratio of 56.2%. As shown in FIG. 6, the mesh metal film illustrated as the white part is discontinuous here and there. Under the above surface state, the mesh metal film remains discontinuous so that a voltage may not be applied to the piezoelectric film 12. In other words, the primary electrode 13a does not function as an electrode any more.

Referring to FIG. 7, there is shown a surface state of the primary electrode 13a formed on the side of the piezoelectric film 12 under a metal film occupation ratio of 61.4%. As shown in FIG. 7, the mesh metal film illustrated as the white part remains fully continuous. Under the above surface state, the mesh metal film remains continuous through all the side of the piezoelectric film 12 so that a voltage may be applied to the piezoelectric film 12.

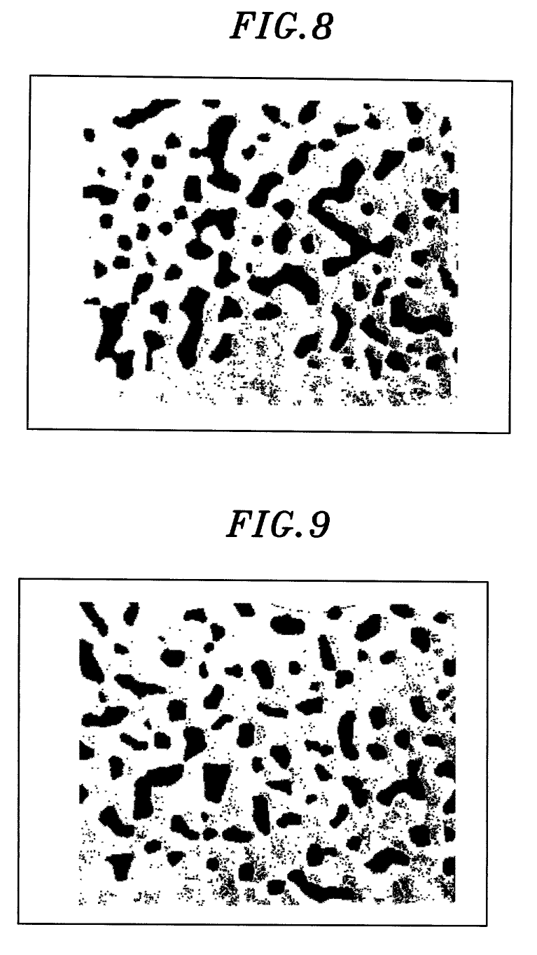

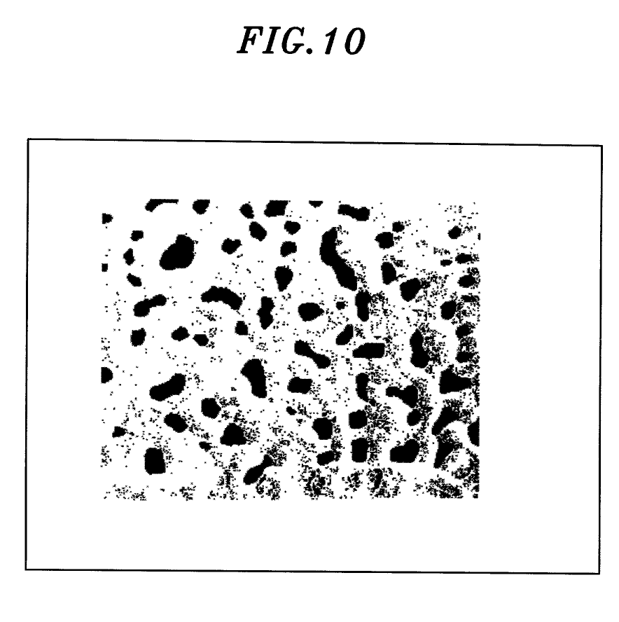

Referring to FIGS. 8 to 10, there are shown surface states of the primary electrode 13a formed on the side of the piezoelectric film 12 under metal film occupation ratios of 76.3%, 81.7% and 85.4%, respectively. As shown in FIGS. 8 to 10, the mesh metal film illustrated as the white part remains fully continuous. However, as shown in FIGS. 9 and 10, the mesh metal film with the metal film occupation ratio of 80% or more may not have the mesh shape any more while all the sides of the surface of the piezoelectric film 12 are substantially coated with the metal film so that a portion on which there is no the metal film may be reduced. Under this state, the metal film may restrict the vibration of the piezoelectric film 12 due to a voltage applied thereto so that the decrement of the sound pressure may not be reduced. In other words, a higher sound pressure level may not be obtained by using the piezoelectric film 12 with a smaller diameter in accordance with the present invention.

In this point, in order to obtain the continuity of the primary electrode 13a coated on the side of the piezoelectric film 12 and to control the sound pressure decrement to be 3.0 dB or less, the metal film occupation ratio on the side of the piezoelectric film 12 ranges preferably from 60% to 85% and more preferably from 60% to 80%.

As described above, since there is no metal film on some portions of the primary electrode 13a under the metal film occupation ratio of 60% to 80%, the primary electrode 13a may be sparsely coated in inverse proportion to the metal film occupation ratio. Since a soldering material has a bad adherence with the metal film under the metal film occupation ratio of 60% to 80, the metal film occupation ratio of 60% to 80% may not be suitable to solder, e.g., the lead.

Therefore, as shown in FIGS. 1 to 4, a plurality of contact electrodes 13b which have a higher metal film occupation ratio than that of the primary electrode 13a are spottedly installed along the inside of the circumference of the primary electrode 13a. It is preferable that the metal film occupation ratio of the contact electrodes 13b is 95% or more depending on the soldering characteristics.

Further, if the area of the contact electrode 13b is small, a larger contact angle of the soldering material on the surface of the contact electrode 13b is required when a quantity of soldering material required to solder a wiring lead to the contact electrode 13b is given so that the height of the soldering material may not be controlled to be low. Therefore, the area of the contact electrode 13b may be controlled in order that the contact angle of the soldering material is about 60 degrees or less and the height of the soldering material is not high.

Specifically, when the amount of the soldering material required to solder the wiring lead is 3 mm³ and the circular contact electrode 13b has a diameter of 1.3 mm, the contact angle of the soldering material is about 63 degrees and the height of the soldering material is controlled to be 4 mm or less. Accordingly, the diameter of the contact electrode 13b is preferably to be 1.3 mm or more.

In order to form the contact electrode 13b which has a larger metal film occupation ratio, a thicker conducting paste must be coated than that of the primary electrode 13a and then heat-treated. For example, if a silver paste is used as the conducting paste to form the primary electrode 13a, it must be coated with a thickness of about 2.2 μm while, if it is used to form the contact electrode 13b, it must be thickly coated with a thickness of about 4.0 μm. If the conducting paste is coated with a thickness of about 4.0 μm, an average film thickness of the metal film at the contact electrode 13b is 2 μm or more after the conducting paste is heat-treated. After, for example, the conducting paste is thinly coated with a thickness of about 2.2 μm to uniformly form the primary electrode 13a on the side of the piezoelectric film 12 and dried, only the portions on which the contact electrode 13b is formed are coated with the conducting paste so that the total coating thickness of the conducting paste may be controlled to be thick with a thickness of about 4.0 μm to obtain a thickly coated conducting paste to form the contact electrode 13b.

Only one contact electrode 13b to connect the lead is required in the unimorph piezoelectric vibrator. In the meantime, in the bimorph piezoelectric vibrator 10, two contact electrodes 13b on the primary electrode 13a of at least one piezoelectric device 16 are required because the lead is naturally connected and, further, two primary electrodes 13a of two piezoelectric devices 16 formed on two surfaces of the vibration plate 11 must be connected.

Since, however, two leads 40 and 41 are used to connect the connection electrodes 38a and 38b on a frame 30 described above when the piezoelectric vibrator 10 is incorporated in the frame 30, respectively, if the number of the contact electrodes 13b is limited as described above, the position of the contact electrode 13b on each of the connection electrodes 38a and 38b must be predetermined. Further, since an electrode connection lead 14 is used to connect two primary electrodes 13a of two piezoelectric devices 16, respectively, formed on two surfaces of the vibration plate 11 in the bimorph piezoelectric vibrator 10 with each other, two contact electrodes 13b formed on two surfaces of the vibration plate 11 must also be aligned.

Therefore, a plurality of contact electrodes 13b are spottedly installed along the inside of the circumference of the primary electrode 13a in accordance with the embodiment of the present invention. An interval between two neighboring contact electrodes 13b is determined based on the lengths of the leads 40 and 41 or the length of the electrode connection lead 14 which is conventionally used so that the leads 40 and 41 or the electrode connection lead 14 may reach to a plurality of neighboring contact electrodes 13b. Therefore, a complicate alignment process of the contact electrodes 13b is no more required to form the contact electrodes 13b or to incorporate the piezoelectric vibrator 10 into the frame 30.

The holding element 20 is a plat donut or a ring-shaped disc and preferably a molding product made of, for example, plastic, graphite, metal and so on. The inner diameter of the holding element 20 is smaller than the diameter of the vibration plate 11 of the piezoelectric vibrator 10 and the outer diameter of the holding element 20 is larger than the inner diameter of a step 33 of a primary wall 32 of the frame 30 described below.

An inner portion 21 and an outer portion 22 of the holding element 20 is flat while a central portion between the inner portion 21 and the outer portion 22 constitutes a sinuous portion 23 which has a sinuous cross section. The curvature of the sinuous portion 23 is preferably uniform through the inner portion 21 and the outer portion 22 of the holding element 20 as shown in FIG. 2. Further, the radial cross-sectional view of the holding element 20 is preferably identical throughout the holding element 20. The central portion of the holding element 20 may be a simple ring-shaped disc on behalf of the sinuous portion as described above.

The frame 30 made of metal or resin has the ring-shaped primary wall 32. Around the middle of the inner cylindrical surface of the primary wall 32, a cylindrical step 33 is surrounded. As described above, the inner diameter of the step 33 is smaller than the outer diameter of the holding element 20 and the outer diameter of the step 33, i.e., the inner diameter of the primary wall 32 is slightly larger than the outer diameter of the holding element 20.

Two supporting portions 34 are projected from the lower portion of the outer surface of the primary wall of the frame 30, wherein two supporting portions 34 are incorporated with the frame 30 and parallel to each other. Further, through the two supporting portions 34, the insulator 31 is fixed to the frame 30. As shown in FIGS. 1 to 3, a pair of terminals 35a and 35b made of Au metal film and so on is formed on the surface of the insulator 31. Further, as shown in FIGS. 2 and 4, a pair of connection electrodes 38a and 38b made of metal film is located between two supporting portions 34 under the lower surface of the insulator 31. As shown in FIG. 2, two terminals 35a and 35b and two connection electrode 38a and 38b are connected to each other through two through-hole conductors 39a and 39b which are formed through the insulator 31, respectively (only one through-hole conductor 39b is shown while the other through-hole conductor 39a is not shown).

As shown in FIGS. 1 and 2, a concave groove 36 is formed toward the outside of the primary wall 32 at the inside of the primary wall 32 of the frame 30 and at the upside of the step 33. The concave groove 36 may not be formed along all the inside circumference of the primary wall 32 while, for example, it may be formed at only a part of the inside of the primary wall 32 as shown in FIGS. 1 and 2. Specifically, The concave groove 36 is formed around a part on which two terminals 35a and 35b are. The electrode connection lead 14, which is used to connect the contact electrodes 13b with each other formed on two surfaces of the bimorph piezoelectric vibrator 10, goes through the concave groove 36 as described below. It is natural that the concave groove 36 may be formed around any other part on which there are no terminals 35a and 35b. Further, if a unimorph piezoelectric vibrator is used, the concave groove 36 is not required since the electrode connection lead 14 need not be used to connect two contact electrodes 13b.

As shown in FIGS. 1 and 4, there is a cutoff portion around which the connection electrode 38b is installed among the floor of the frame 30. The cutoff portion forms a concave groove 42.

Hereinafter the structure of piezoelectric vibration apparatus having components described above will be illustrated with an assembling sequence. After the outer portion of the vibration plate 11 puts on the inner portion 21 of the holding element 20, the vibration plate 11 adheres to the holding element 20 by an elastic adhesive such as a silicon adhesive.

Then, two contact electrodes 13b on two primary surfaces of the piezoelectric vibrator 10 are connected with each other by the electrode connection lead 14. As described above, there are installed a plurality of contact electrodes 13b along the inside of the circumference of the primary electrode 13a on each of two surfaces of the piezoelectric vibrator 10. Accordingly, the nearest two contact electrodes 13b are selected and connected with two ends of the electrode connection lead 14, respectively. The middle potion of the electrode connection lead 14 is wound around the outer portion of the holding element 20.

The outer portion 22 of the holding element 20 with the piezoelectric vibrator 10 mounted thereon is inserted into the inner portion of the frame 30 so that the outer portion 22 of the holding element 20 may be laid on the step 33. The electrode connection lead 14 which is wound around the outer portion of the holding element 20 is inserted into the concave groove 36 of the frame 30. The outer portion 22 of the holding element 20 is attached to the step 33 of the frame 30 by the elastic adhesive 37 such as the silicon adhesive. As shown in FIG. 2, the concave groove 36 is also filled with the elastic adhesive 37. Referring to FIG. 3, there is shown a top view of the frame 30 with the piezoelectric vibrator 10 incorporated therein.

As shown in FIGS. 2 and 4, two connection electrodes 38a and 38b formed on the lower side of the insulator 31 are connected with the vibration plate 11 of the piezoelectric vibrator 10 and the contact electrode 13b on the lower side of the piezoelectric vibrator 10, respectively. Two leads 40 and 41 are used to connect two connection electrodes 38a and 38b with the vibration plate 11 and the contact electrode 13b, respectively, and a soldering material 15 is used to attach two corresponding ends. As shown in FIGS. 1 to 4, another contact electrode 13b near to the contact electrode 13b connected to the electrode connection lead 14 is connected with the connection electrode 38a through the lead 41 while the surface of the vibration plate 11 at outward of the contact electrode 13b is connected with the connection electrode 38b through the lead 40. As described above, there is a concave groove 42 under a portion of the frame 30 and the supporting portion 34. The leads 40 and 41 are extended from the inner side of the frame 30 to the outside of the frame 30 through the concave groove 42 and, then, are soldered to the connection electrodes 38a and 38b, respectively.

The leads 40 and 41 and the electrode connection lead 14 and the soldering material portion 15 therefor are applied with, e.g., the silicon resin and then the applied silicon resin is hardened. As shown in FIGS. 2 to 4, the leads 40 and 41 and the electrode connection lead 14 and the soldering material portion 15 are coated so that they may be protected by the resin coating portion 43. The resin coating portion 43 is formed on two primary surfaces of the piezoelectric vibrator 10. Therefore, the leads 40 and 41 or the electrode connection lead 14 may not be short-circuited or the soldering material portion 15 may not be removed.

As described above, two primary electrodes 13a of the piezoelectric device 16 on two primary surfaces of the vibration plate 11 are connected with each other by the electrode connection lead 14. Further, the two connection electrodes 38a and 38b connected by two leads 40 and 41 are connected through two through-hole conductors 39a and 39b with the terminals 35a and 35b on the upper surface of the supporting portion 34, respectively. Accordingly, the terminals 35a and 35b are used to apply a voltage to the piezoelectric films 12 on two primary surfaces of the vibration plate 11 so that the piezoelectric vibrator may be vibrated to make a sound.

### EXAMPLE 2

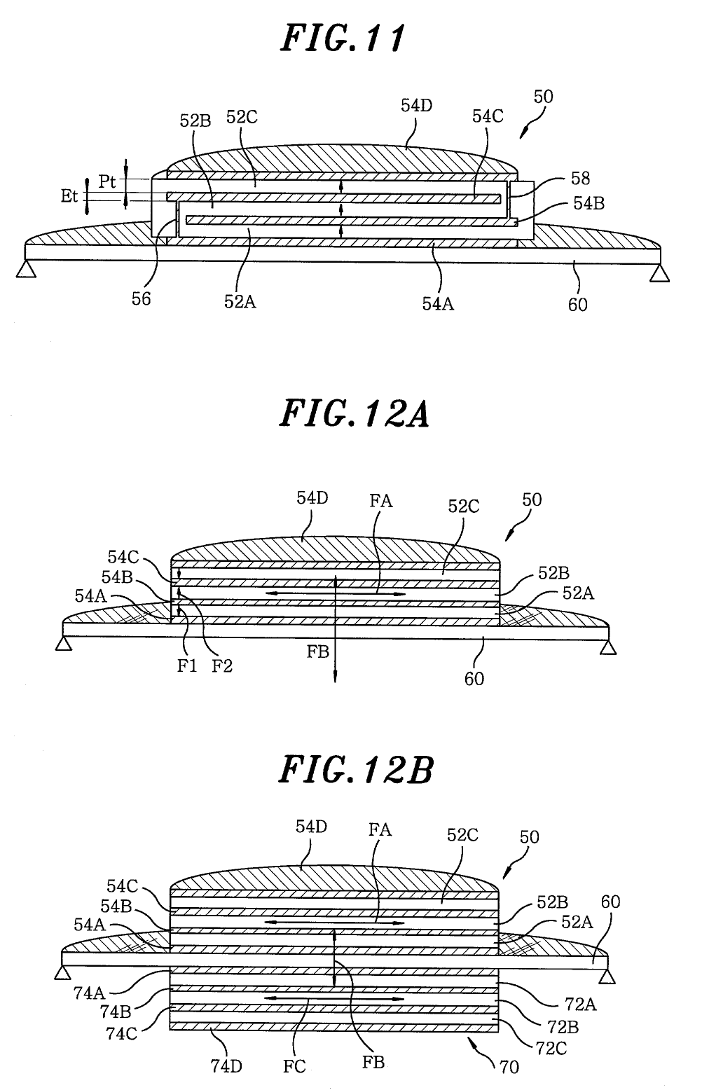

Referring to FIGS. 11 to 13, there is shown another embodiment of the present invention. In case the piezoelectric vibrator is used as a speaker for a cellular phone, the driving voltage must be preferably small. Since the amplitude of the sound depends on the absolute value of the displacement of the piezoelectric vibrator, the more driving energy is required to make a loud sound. The driving energy E of the unimorph or the bimorph vibrator in accordance with the present invention may be calculated as follows:

$$E \approx \frac{1}{2} \cdot \frac{{d}_{31} \cdot {V}^{2} \cdot {D}^{2}}{{S}_{31}} \cdot \frac{n}{t}$$

wherein d₃₁ is a transverse component of a piezoelectric strain constant of the piezoelectric material, S₃₁ is a transverse component of an elastic compliance, D is a diameter of the piezoelectric device and V is an applied voltage.

Accordingly, other than changing the piezoelectric material itself, the driving energy E can be increased by increasing the diameter D and raising the applied voltage V, to thereby increase the sound. The term n/t is a new parameter in accordance with the present invention, wherein t is a thickness of the ceramic and n is a stacking number of the ceramic. Accordingly, a number of more laminated ceramic sheets must be stacked to increase the driving energy E.

In this regard, it is preferable that the piezoelectric device has a stacking structure since the more piezoelectric films must be stacked in order to obtain a larger driving power with a smaller driving voltage. However, if a number of thick ceramic sheets are stacked to increase the total thickness of the ceramic sheets, the vibration of a sounding body may be consequently restrained by the rigidity of the stacked thick ceramic sheets. Accordingly, in order to increase the stacking number of the piezoelectric films from a viewpoint of a thin and light electronic device, the piezoelectric film and the electrode should be allowed to be thin. If, however, the thickness of one piezoelectric film is entirely too thin, the stacked piezoelectric films may not become rigid enough. Further, the piezoelectric device may be bent or broken during the firing process thereof so that a mass production may not be accomplished.

If the thickness of one electrode is too thin, the electrode may not be able to function as the electrode and, therefore, the electrode must have a certain amount of thickness. Although a thick electrode is preferable, the displacement of the piezoelectric film may be restrained by the thick electrode and, therefore, the piezoelectric film with the thick electrode may not be good to be used as the piezoelectric vibrator.

Accordingly, in case a plurality of piezoelectric films and electrodes are alternately stacked and cofired to form a piezoelectric device, the ratio of a thickness Pₜ of each piezoelectric film and a thickness Eₜ of each electrode may be given as follows:

$$0.02 \leq \frac{{E}_{t}}{{P}_{t}} \leq 0.30$$

However, the relation may preferably be modified as follows:

$$0.04 \leq \frac{{E}_{t}}{{P}_{t}} \leq 0.25$$

And the relation may be still further modified as follows:

$$0.1 \leq \frac{{E}_{t}}{{P}_{t}} \leq 0.2$$

Under such structure of the piezoelectric film and the electrode, a piezoelectric device which may vibrate with a sufficient displacement, have a good rigidity and comply with a thinner and lighter piezoelectric device and a good mass production may be accomplished. Further, piezoelectric vibrator with the piezoelectric device incorporated therein may be obtained.

Referring to FIG. 11, there is shown an enlarged primary view of the piezoelectric vibrator in accordance with the second embodiment of the present invention and, referring to FIG. 12A, there is a cross-sectional view of the piezoelectric vibrator shown in FIG. 11. As shown in FIGS. 11 and 12A, the piezoelectric device has a stacking structure. The unimorph piezoelectric vibrator with a disc shape has a vibration plate 60 and a piezoelectric device 50 attached thereon.

The piezoelectric device 50 has a structure in which a plurality of piezoelectric films 52A to 52C made of piezoelectric translator (PZT) and a multiple of electrodes 54A to 54D are alternately stacked. A predetermined number of piezoelectric films 52A to 52C and another predetermined number of the electrodes 54A to 54D are alternately stacked and, then, are cofired on the whole to form the piezoelectric device 50. The piezoelectric device 50 is attached around the center of the vibration plate 60 by an adhesive material.

The electrode 54D which coats the primary surface which is opposite to the surface on which the vibration plate 60 is attached functions as a primary electrode in accordance with the present invention. A plurality of contact electrodes (not shown) are spottedly installed along the inside of circumference of the primary surface of the electrode 54D as described in Example 1. Further, a conduction paste is thinly coated on the surfaces of the piezoelectric films 52A to 52C and heat-treated to form the electrodes 54A to 54D with a mesh shape as described in Example 1.

All the electrodes 54A to 54D may be formed with the mesh shape while only some portions of the electrodes 54A to 54D may be formed with the mesh shape. Further, if all the electrodes 54A to 54D are equally printed, the continuity of two interior electrodes 54B and 54C is higher than that of two exterior electrodes 54A and 54D and the growth in thickness in two interior electrodes 54B and 54C may be restrained. The contact electrodes may be formed as described in Example 1.

The contact electrode 54A is connected through a through-hole 56 with the contact electrode 54C and the contact electrode 54B is connected through a through-hole 58 with the contact electrode 54D. Since the electrodes are alternately connected by two through-holes 56 and 58, every two neighboring electrodes have opposite electrodes. The electrode 54A (or the vibration plate 60) and the electrode 54D are connected through the leads with the terminals (not shown), respectively. The electrode 54D is connected through the connect electrode with the lead.

If a polarizing voltage is applied to the electrodes 54A to 54D, the piezoelectric films 52A to 52C may be polarized with a predetermined amount. Two neighboring piezoelectric films are oppositely polarized. For example, if two piezoelectric films 52A and 52C are polarized along a direction F1, the other piezoelectric film 52B may be polarized along another direction F2 opposite to the direction F1. For example, two electrodes 54A and 54C are applied with a negative voltage and two electrodes 54B and 54D are applied with a positive voltage, three piezoelectric films 52A to 52C are polarized along the directions F1 and F2. The vibration plate 60 is made of metal and so on. The piezoelectric device 50 is attached to the vibration plate 60 with, e.g., an adhesive material. The circumference of the vibration plate 60 is fixed with an appropriate means.

The basic operation of the piezoelectric vibrator will be described. For example, two electrodes 54A and 54D are applied with a driving voltage such as a voice signal while two electrodes 54A and 54C are connected to a welding ground. Since the voltage direction in the piezoelectric films 52A to 52C is equal to the polarization direction therein, the piezoelectric films 52A to 52C are simultaneously expanded and contracted along the direction FA. Since, however, there is the vibration plate 60, all the piezoelectric films 52A to 52C are curved so that they are operated along the direction FB. Since the thickness of the piezoelectric film with a stack structure in accordance with the present invention is thinner than that in the conventional piezoelectric film with the non-stack structure, the piezoelectric film may be operated with a lower driving voltage.

As shown in FIG. 11, Pt is the thickness of the piezoelectric films 52A to 52C while Et is the thickness of the electrodes 54A to 54D. If each of the electrodes 54A to 54D becomes thicker, the electrodes 54A to 54C may restrain the deformation of the piezoelectric films 52A to 52C so that the piezoelectric vibrator itself may not be easily displaced. Since, however, the displacement of the piezoelectric vibrator depends on the thickness of the piezoelectric films 52A to 52C, the thickness of the electrodes 54A to 54D may be increased. In this point, it is preferable that the thickness Pt of each of the piezoelectric films 52A to 52C and the thickness Et of each of the electrodes 54A to 54D must be controlled to maximize the displacement of piezoelectric vibrator.

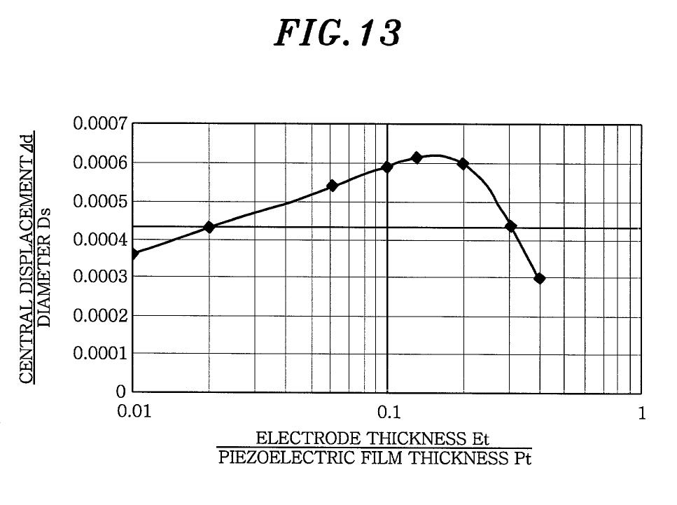

Referring to FIG. 13, there is shown an experimental graph in which a central displacement in terms of diameter depends on the ratio of the thickness Et of the electrodes 54A to 54D to the thickness Pt of the piezoelectric films 52A to 52C. X axis represents the ratio Et/Pt of the thickness Et of each of the electrodes 54A to 54D to the thickness Pt of each of the piezoelectric films 52A to 52C. Y axis represents the ratio Δd/DS of the central displacement Δd along the direction FB (shown in FIG. 12A) to the diameter DS (shown in FIG. 12A) of the vibration plate 60. Y axis is in logarithmic scale.

As shown in FIG. 13, since Δd/DS is larger than about 0.0004 at the Et/Pt range of 0.02 to 0.30, a practical displacement of the piezoelectric vibrator may be obtained. Further, since Δd/DS is larger than 0.0005 at the Et/Pt range of 0.04 to 0.25 and Δd/DS is larger than 0.0006 at the Et/Pt range of 0.1 to 0.2, a satisfying displacement may be obtained.

The practical thickness of each of piezoelectric films 52A to 52C preferably ranges about 6 μm to about 50 μm when the productivity of piezoelectric films are taken into consideration. Further, the thickness of each of the electrodes 54A to 54D is thicker than about 1 μm when the productivity of the electrodes are taken into consideration. Accordingly, if those conditions are combined with the Et/Pt condition to obtain the piezoelectric device, a sufficient displacement may be obtained with a lower voltage and a sufficient rigidity, slimness and lightness may be realized.

The present invention may be variably changed based on the embodiments in accordance with the present invention.

(1) The material, the shape and, especially, the stack structure of the piezoelectric device shown in the embodiment of the present invention must be considered as an example and, therefore, a number of modifications may be realized to perform the same function.

(2) Although the stack piezoelectric device has been applied to only the unimorph piezoelectric vibrator in Example 1, it may be applied to the bimorph piezoelectric vibrator. Referring to FIG. 12B, there is shown an example of the bimorph piezoelectric vibrator, wherein a piezoelectric device 50 is installed on a surface of the vibration plate 60 and another piezoelectric device 70 is installed on the other surface of the vibration plate 60. In the piezoelectric device 70, a plurality of piezoelectric films 72A to 72C and a number of electrodes are alternately stacked. The piezoelectric device 70 is attached on the vibration plate 60 with the adhesive material. The polarization directions of the piezoelectric films 72A to 72C are opposite to those of electrodes 74A to 74D.

The driving voltages related to the voice signal and so on are applied to the electrodes 54A, 54D, 74A and 74D, respectively, while the other electrodes are connected to a common terminal. Accordingly, the expansion of the piezoelectric device 50 along the direction FA is opposite to that of the piezoelectric device 70 along the direction FC. In other words, if the piezoelectric device 50 is expanded along the direction FA, the piezoelectric device 70 is contracted along the direction FB. On the contrary, if the piezoelectric device 50 is contracted along the direction FA, the piezoelectric device 70 is expanded along the direction FC. Accordingly, overall, the vibration plate 60 and the piezoelectric devices 50 and 70 will vibrate along the direction FB.

(3) The piezoelectric vibrator in accordance with the present invention may be used as a speaker for a plurality of electronic devices such as cellular phones, personal digital assistants (PDA), voice recorders, personal computers (PC) and so on.

As described above, since the primary electrode on the primary side of the piezoelectric film of the piezoelectric vibrator is made of a mesh metal film and there is no metal film except the mesh metal film, the deforming restraint of the piezoelectric film by the primary electrode may be reduced. Since, further, the primary electrode is continuous, a voltage may be applied on the piezoelectric film. Accordingly, since a voice signal is applied to the piezoelectric film in order for the piezoelectric vibrator to generate a sound and the piezoelectric vibrator may more easily be curved, the piezoelectric vibration apparatus for using the piezoelectric vibrator therein may obtain a higher sound pressure.

Further, since the spotted soldering contact electrodes are installed along the inside of the circumference of the primary electrode, the contact electrode is used to securely fix the soldering material thereon. Since a plurality of spotted soldering contact electrodes are installed on a plurality of spots arranged with a substantially equiangular distance along the inside of the circumference of the primary electrode, a predetermined contact electrode may not be arranged along a predetermined direction and may be set on the frame along a predetermined direction so that the manufacturing process for the piezoelectric vibrator or the piezoelectric vibration apparatus may be simplified.

In case a number of piezoelectric films and a multiple of electrodes are alternately stacked and cofired to produce the piezoelectric device which is attached on the vibration plate to form the piezoelectric vibrator, a ratio Eₜ/Pₜ of a thickness Eₜ of each electrode to a thickness Pₜ of each piezoelectric film ranges as follows:

$$0.02 \leq \frac{{E}_{t}}{{P}_{t}} \leq 0.30 .$$

The ratio Eₜ/Pₜ of a thickness Eₜ of each electrode to a thickness Pₜ of each piezoelectric film preferably ranges as follows:

$$0.04 \leq \frac{{E}_{t}}{{P}_{t}} \leq 0.25 .$$

The ratio Eₜ/Pₜ of a thickness Eₜ of each electrode to a thickness Pₜ of each piezoelectric film more preferably ranges as follows:

$$0.1 \leq \frac{{E}_{t}}{{P}_{t}} \leq 0.2$$

Accordingly, the piezoelectric film may be sufficiently displaced. The piezoelectric vibrator and the piezoelectric vibration apparatus for using the piezoelectric vibrator may have a sufficient rigidity, slimness and lightness.

In a method for manufacturing the piezoelectric vibrator or the piezoelectric vibration apparatus in accordance with the present invention, the conduction paste is applied on the primary side of the piezoelectric film formed on the primary surface of the piezoelectric vibrator and it is heat-treated to generate the primary electrode which substantially uniformly coats the primary side of piezoelectric film. Since the coherence of the conduction paste results in the primary electrode made of the continuous mesh metal film, the mesh metal film may easily be formed.

While the invention has been shown and described with respect to the preferred embodiments, it will be understood by those skilled in the art that various changes and modifications may be made without departing from the spirit and scope of the invention as defined in the following claims.

What is claimed is:

1. A piezoelectric vibrator, comprising
a vibration plate having a primary surface; and
a piezoelectric device attached on the primary surface of the vibration plate, wherein the piezoelectric device includes a piezoelectric film and two electrodes formed on two sides of the piezoelectric film,
wherein one of the two sides of the piezoelectric film on which the vibration plate is not attached is a primary side and one electrode of two electrodes formed on the primary side is a primary electrode;
wherein the primary electrode is substantially uniformly coated on the primary side and made of a continuous mesh metal film.

2. The piezoelectric vibrator of claim 1, wherein a metal film occupation ratio of the continuous mesh metal film to the primary side of the piezoelectric film in the primary electrode ranges from about 60% to about 80%.

3. The piezoelectric vibrator of claim 1, further comprising a contact electrode formed along the inside of the circumference of the primary electrode, wherein the contact electrode is made of spotted metal film.

4. The piezoelectric vibrator of claim 3, wherein a metal film occupation ratio of the spotted metal film to the primary side of the piezoelectric film in the contact electrode is equal to or larger than about 90%.

5. The piezoelectric vibrator of claim 3, wherein the contact electrode is divided into one or more contact electrodes, wherein the contact electrodes are installed on a plurality of spots arranged with a substantially equiangular distance along the inside of the circumference of the primary electrode.

6. The piezoelectric vibrator of claim 3, wherein the equiangular distance is determined based on a length of a lead, wherein the lead reaches to one or more contact electrodes.

7. The piezoelectric vibrator of claim 1, wherein the piezoelectric device is made of a number of piezoelectric films and a multiple of electrodes alternately stacked and cofired.

8. The piezoelectric vibrator of claim 7, wherein a ratio Eₜ/Pₜ of a thickness Eₜ of each electrode to a thickness Pₜ of each piezoelectric film is calculated as follows:
$$0.02 \leq \frac{{E}_{t}}{{P}_{t}} \leq 0.30 .$$

9. The piezoelectric vibrator of claim 7, wherein a ratio Eₜ/Pₜ of a thickness Eₜ of each electrode to a thickness Pₜ of each piezoelectric film is calculated as follows:
$$0.04 \leq \frac{{E}_{t}}{{P}_{t}} \leq 0.25 .$$

10. The piezoelectric vibrator of claim 7, wherein a ratio Eₜ/Pₜ of a thickness Et of each electrode to a thickness Pₜ of each piezoelectric film is calculated as follows:
$$0.1 \leq \frac{{E}_{t}}{{P}_{t}} \leq 0.2$$

11. A piezoelectric vibration apparatus for using the piezoelectric vibrator of claim 1.

12. The piezoelectric vibration apparatus of claim 11, further comprising a frame having an inner portion for supporting the circumference of the piezoelectric vibrator.

13. A method for manufacturing the piezoelectric vibrator of claim 1, wherein the mesh metal film is formed by a coherence process of a conduction paste.
